(19) United States
(12) Patent Application Publication
(10) Pub. No.: US 2026/0113025 A1
(43) Pub. Date: Apr. 23, 2026

(54) HAND-OFF-AUTO SWITCH ASSEMBLY WITH POSITION DETECTION AND ALARM CIRCUIT

(71) Applicant: Evapco, Inc., Taneytown, MD (US)

(72) Inventor: Arthur J. Marshall, Gettysburg, PA (US)

(21) Appl. No.: 19/358,191

(22) Filed: Oct. 14, 2025

Related U.S. Application Data
(60) Provisional application No. 63/706,505, filed on Oct. 11, 2024.

(51) Int. Cl. H03K 17/00

(52) U.S. Cl. CPC H03K 17/005

(57) ABSTRACT

A Hand-Off-Auto (“H-O-A”) toggle switch configured to be located between a supervisory PLC and a field device, the H-O-A toggle switch having a control circuit having Hand (manual), Off and Auto positions, and a switch position detection circuit with an alarm output to indicate that the H-O-A switch is not in the “Auto” position

### FIELD OF THE INVENTION

This invention relates to Hand-Off-Auto switches and supervisory control systems.

### BACKGROUND OF THE INVENTION

A Hand-Off-Auto (H-O-A) switch assembly is typically used in industrial supervisory control systems but can be implemented in many other applications. An H-O-A switch is typically located between a supervisory controller, such as a Programmable Logic Controller (PLC) and a field connected device to be controlled. The purpose of an H-O-A switch is to provide a way to override the supervisory PLC signal to the field connected device for emergency and maintenance purposes. When the H-O-A switch is set to the “Auto” position, the supervisory controller operates the field connected device. “Auto” is the “normal” position for the H-O-A switch. If it is desired to disconnect the field connected device from the supervisory controller, the H-O-A switch is set to the “Off” position. If it is desired to continuously enable the field connected device, then the H-O-A switch is set to the “Hand” position. Setting the H-O-A switch to “Off” or “Hand” is designated for emergency or maintenance purposes and is not a desirable situation for the long-term operation of the system. Therefore, the “Auto” position is the typical default setting for proper operation of the system.

### SUMMARY OF THE INVENTION

There is provided according to the invention a Hand-Off-Auto (“H-O-A”) toggle switch configured to be located between a controller and a device, the H-O-A toggle switch comprising a control circuit having Hand (manual), Off and Auto positions, and a switch position detection circuit with an alarm output to indicate that the H-O-A switch is not in the “Auto” position. The controller may be a supervisory programmable logic controller (“PLC”) and the alarm output may be sent to the supervisory PLC.

There is also provided according to the invention a circuit board comprising a plurality of H-O-A toggle switches, each H-O-A toggle switch configured to receive a plurality of supervisory PLC outputs and to transmit control signals to a plurality of field devices, each H-O-A toggle switch comprising a control circuit having Hand (manual), Off and Auto positions, the circuit board further comprising a switch position detection circuit connected to each of the plurality of H-O-A toggle switches and to the alarm circuit, the switch position detection circuit configured to activate the alarm circuit if any one of the plurality of H-O-A toggle switches is not in the “Auto” position.

It is specifically noted that every combination and sub-combination of the above-listed and below-described features and embodiments is considered to be part of the invention.

### BRIEF DESCRIPTION OF DRAWINGS

The foregoing summary, as well as the following detailed description of the preferred invention, will be better understood when read in conjunction with the appended drawings. For the purposes of illustrating the invention, there are shown in the drawings embodiments which are presently preferred. It should be understood, however, that the invention is not limited to the precise arrangements and instrumentalities shown. In the drawings:

FIG. 1 is a representation of a first side of an H-O-A switch according to an embodiment of the invention.

FIG. 2 is a representation of a second side (alarm circuit side) of an H-O-A switch according to an embodiment of the invention.

FIG. 3 is a schematic of an eight switch H-O-A switch assembly according to an embodiment of the invention.

FIG. 4 is a labeled version of FIG. 3.

FIG. 5 is a circuit diagram an eight switch H-O-A switch assembly according to an embodiment of the invention.

FIG. 6 is a labeled version of FIG. 5.

### DETAILED DESCRIPTION OF THE INVENTION

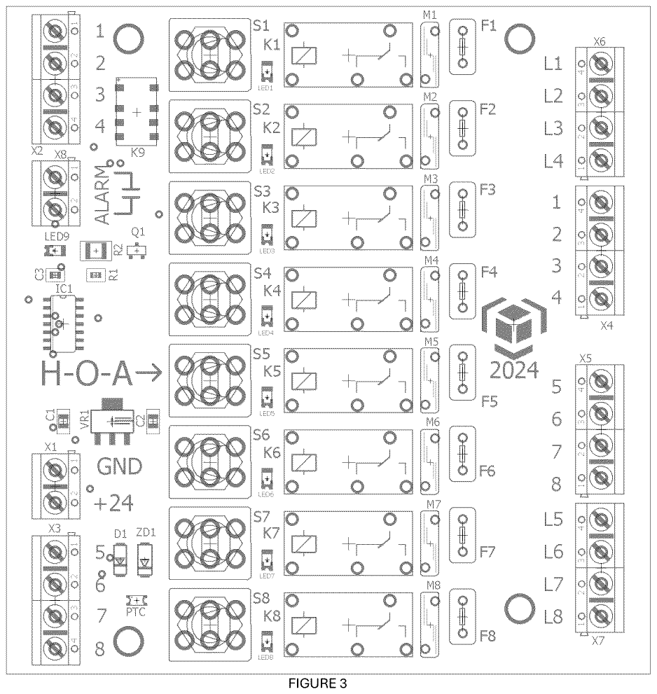

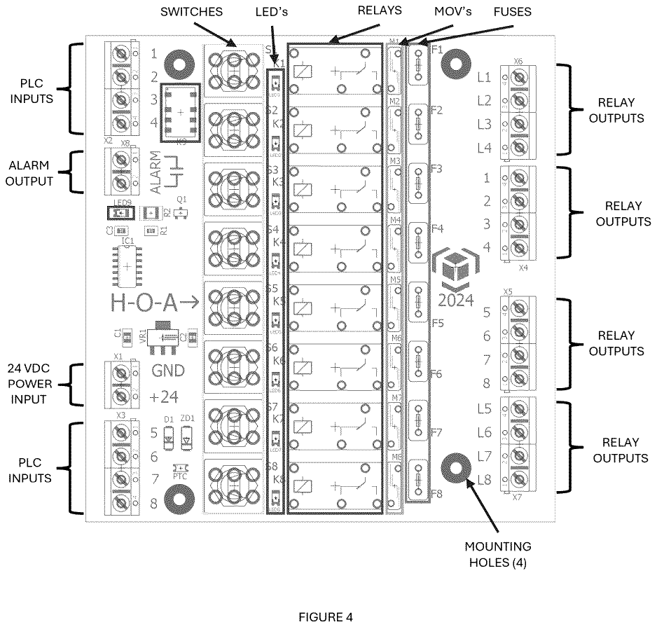

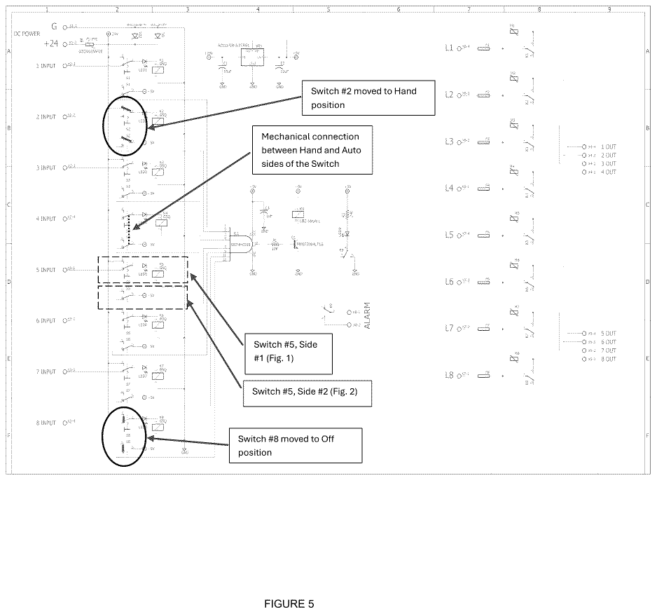

The H-O-A switch of the invention can be configured in a number of ways. According to one embodiment, eight switch assemblies are configured on a circuit board mounted a plastic carrier (FIGS. 3 and 4). The plastic circuit board carrier is then easily mounted on a DIN-rail within the system supervisory control panel. Eight switches make it compatible with most PLC controllers which have either eight or sixteen outputs. In this case, two H-O-A switch assemblies according to the eight-switch embodiment may be implemented for sixteen output PLC's, while one H-O-A switch assembly may be implemented for eight output PLC's. While the exemplary embodiment disclosed herein is an eight-switch assembly, the H-O-A switch assembly of the invention may be configured from one to as many number of switches as desired. A supervisory control system may have hundreds of outputs which would require multiple H-O-A switch assemblies mounted in or near the system supervisory control panel. In some cases, the H-O-A switch assembly could be mounted in remote panels within the system. The H-O-A switch assembly includes four mounting holes in the circuit board which would eliminate the plastic circuit board carrier and can be direct-mounted to a control panel via, stand-off's.

This exemplary embodiment disclosed herein assumes that the PLC control signals are 24 volts, Direct Current (DC). Therefore, a power relay is implemented on the circuit board to provide “dry contact” outputs. The dry contacts provide a means to use different voltages from 1 to 250 volts AC or DC. Each H-O-A switch circuit on the eight-position assembly can control different voltages on each of the relay outputs. The circuit board provides an LED indicator for each relay when energized. A relay contact suppression device (MOV) protects the relay contacts. A replaceable fuse is provided for each of the eight circuits. Pluggable field connectors may be provided for easy field wiring. The 24 VDC input power circuit is protected against over voltage and reverse voltage.

The H-O-A switch assembly can be configured in many other input/output voltage formats from 5 volts to 250 volts AC or DC. In some of these configurations, the relay may be eliminated to allow a direct signal from the H-O-A switch assembly input to output. The operation of selecting “Hand-Off-Auto” is the same and includes the LED indicator and replaceable fuse.

This H-O-A switch assembly of the invention also employs a “switch position” detection circuit and an alarm output to alert the supervisory PLC that one or more of the switches are NOT in the “Auto” position. When the supervisory system gets an alarm input from any of the H-O-A switch assemblies, an alarm can be indicated on the operator interface alerting that a field connected device is not being controlled by the system.

According to an optional feature of the invention, in order to use common digital logic devices, a voltage regulator may be used to reduce the 24 VDC to 5 VDC. There are digital logic devices that operate from 1.5 VDC to 18 VDC. Depending on the device selected, an appropriate voltage regulator may be selected to reduce 24 VDC to anywhere from 1.5 VDC to 18 VDC. Diode-Transistor-Logic (DTL) may also be implemented to eliminate the need for a voltage regulator and would perform the same logic. For the exemplary embodiment described herein, 5 VDC logic was chosen due to availability of logic devices, reduced component count and cost.

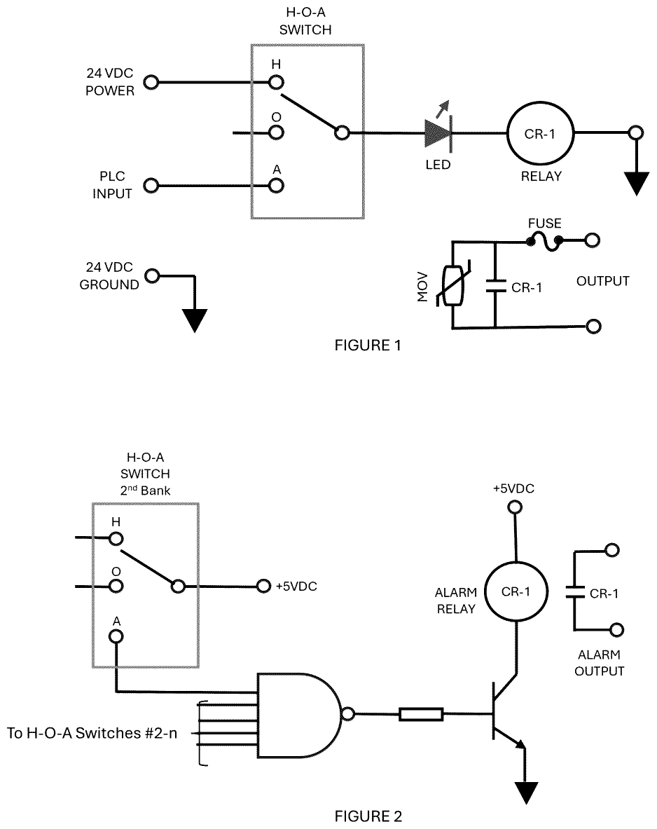

For the exemplary embodiment described herein, a double pole, 3-position toggle switch is used. The first side of the toggle switch (FIG. 1) operates the H-O-A function from the PLC to the output of the H-O-A switch assembly. The second side of the toggle switch (FIG. 2) is used to detect the position of the switch in Hand-Off-Auto. A single pole toggle switch may be used as well but would increase the logic circuit complexity somewhat. Referring to FIG. 5, side 1 and side 2 of each switch is mechanically connected by a mechanical switch device, as represented by the dotted line at Input/Switch 4. Moving the mechanical switch device to an Hand position makes the connections shown at Input/Switch 2. Moving the mechanical switch device to an Off position makes the connections shown at Input/Switch 8.

According to one embodiment, the logic function used to detect the switch position is: “NOT-AUTO”. Therefore, if the switch is in any other position than “Auto” then an alarm is generated. According to alternate embodiments, other logic may be implemented to directly look at all three logic states Hand, Off and Auto, and determine the alarm state, however, the “NOT-AUTO” logic is the most simple and lowest cost embodiment while providing the desired switch detection.

According to another embodiment, a single alarm output is used for the summation of all eight switches on the circuit board. Therefore, if any single switch, or multiple switches are not in “Auto”, an alarm is generated. All eight switches must be in “Auto” to turn the alarm off. According to an alternative embodiment, an alarm output may be provided for each of the eight switches. This would give the supervisory PLC system visibility to every switch in the system but would require eight input channels per H-O-A switch assembly. Assuming there are 128 field connected devices, then 128 input PLC inputs would be required at significant cost. If there is one alarm per H-O-A switch assembly, then only 16 PLC inputs are required for the same application at a much lower cost. The operator would know that a particular H-O-A switch assembly has a switch in Hand or Off and could easily find which switch is not set correctly on that particular H-O-A switch assembly.

The alarm output controls a signal relay with dry contacts. An LED indicator on the circuit board indicates when the alarm relay is energized.

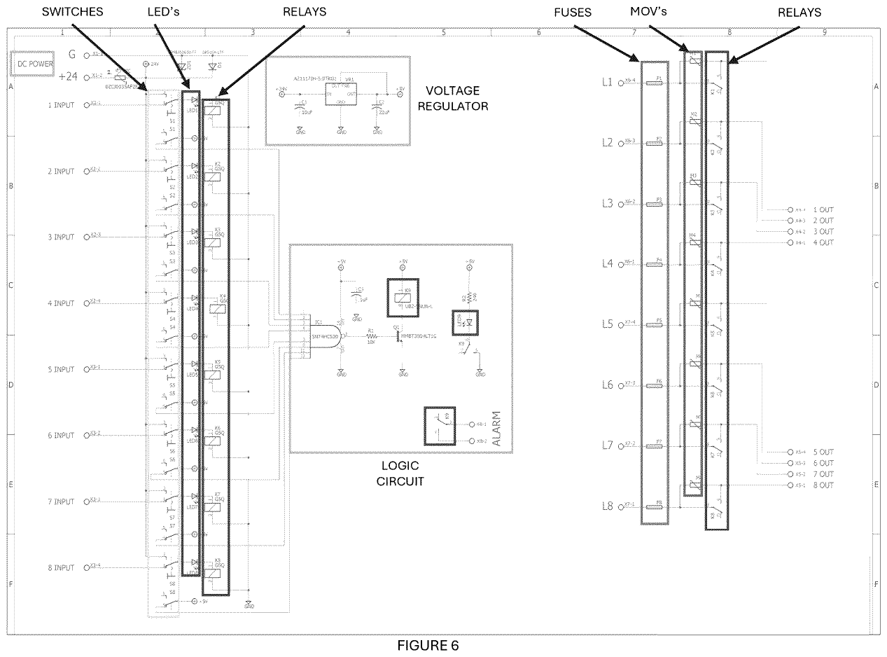

The switch detection circuit preferably uses an eight-input NAND gate (FIGS. 2, 5 and 6) to summate the eight switch positions. When a H-O-A toggle switch is in the “Auto” position, 5 VDC is connected to a NAND gate input. 5 VDC is considered a logic ‘One”. If the toggle switch is in any other position than “Auto, the input to the NAND gate would be logic “Zero”.

The NAND gate will output a logic “Zero” when all of eight inputs are a logic “One”. Therefore, if all of the H-O-A toggle switches are set to “Auto”, then all of the NAND gate inputs would be a logic “One”. In this case, the output of the NAND gate would be logic “Zero”. If the base of the output driver transistor is logic “Zero”, then the transistor is off. If the transistor is off, then the alarm relay is de-energized and the alarm contacts would be open. This is a No-Alarm condition.

A NAND gate will output a logic “One” when one or more of the eight inputs are a logic “Zero”. Therefore, if any H-O-A toggle switch is “NOT-Auto”, the NAND gate will output a logic “One”. If the base of the output driver transistor is logic “One”, then the transistor is on. If the transistor is on, then the alarm relay is energized and the alarm contacts are closed. This is an Alarm condition.

Notwithstanding the specific embodiments, features, elements, combinations and sub-combinations disclosed herein, it is expressly considered and here disclosed that every single element, every single feature, and every combination and sub-combination thereof disclosed herein may be combined with every other element, feature, combination and sub-combination disclosed herein.

It will be appreciated by those skilled in the art that changes could be made to the embodiments described above without departing from the inventive concept thereof. It is understood, therefore, that this invention is not limited to the particular embodiments disclosed, but it is intended to cover modifications within the spirit and scope of the present invention as outlined in the present disclosure and defined according to the broadest reasonable reading of the claims that follow, read in light of the present specification.

1. A Hand-Off-Auto (“H-O-A”) toggle switch configured to be located between a controller and a device, the H-O-A toggle switch comprising a control circuit having Hand (manual), Off and Auto positions, and a switch position detection circuit having corresponding Hand, Off, and Auto positions with an alarm output to indicate that the H-O-A switch is not in the “Auto” position, the control circuit and the switch position detection circuit linked by a switch mechanism configured to move the connections of the control circuit and the switch position detection circuit to corresponding positions.

2. The H-O-A toggle switch of claim 1, wherein the controller is a supervisory programmable logic controller (“PLC”).

3. The H-O-A toggle switch of claim 2, wherein the alarm output is sent to the supervisory PLC.

4. A circuit board comprising a plurality of H-O-A toggle switches, each H-O-A toggle switch configured to receive a plurality of supervisory PLC outputs and to transmit control signals to a plurality of field devices, each H-O-A toggle switch comprising a control circuit having Hand (manual), Off and Auto positions, the circuit board further comprising a switch position detection circuit connected to each of said plurality of H-O-A toggle switches and to alarm circuit, said switch position detection circuit configured to activate said alarm circuit if any one of said plurality of H-O-A toggle switches is not in the “Auto” position.
